(19) United States
(12) Patent Application Publication
(10) Pub. No.: US 2026/0096258 A1
(43) Pub. Date: Apr. 2, 2026

(54) LIGHT EMITTING DIODE DISPLAY DEVICE

(71) Applicant: AUO Corporation, Hsinchu City (TW)

(72) Inventors: Chi-Cheng Chen, Hsinchu City (TW); Chun-Fan Chung, Hsinchu City (TW); Feng-Ming Hsu, Hsinchu City (TW); Chia-Pu Ho, Hsinchu City (TW)

(73) Assignee: AUO Corporation, Hsinchu City (TW)

(21) Appl. No.: 18/957,892

(22) Filed: Nov. 25, 2024

(30) Foreign Application Priority Data
Sep. 30, 2024 (TW) 113137251

(51) Int. Cl. H01L 33/62; H01L 25/16; H01L 27/12

(52) U.S. Cl. CPC H10H 20/857; H10D 86/441; H10D 86/60; H10W 90/00

(57) ABSTRACT

A light-emitting diode (LED) display device includes an LED display panel and a first chip on film package structure. The first chip on film package structure is bonded to the LED display panel and includes a first chip, a second chip and a first circuit board. The first chip includes first signal output bumps and first dummy bumps. The second chip includes second signal output bumps. First signal output lines are electrically connected to the first signal output bumps respectively. Second signal output lines are electrically connected to the second signal output bumps respectively. At least part of the second signal output lines are electrically connected to the first dummy bumps respectively. One of the first chip and the second chip is a light-emitting signal control chip.

### CROSS-REFERENCE TO RELATED APPLICATION

This application claims the priority benefit of Taiwan application serial no. 113137251, filed on September 30, 2024. The entirety of the above-mentioned patent application is hereby incorporated by reference herein and made a part of this specification.

### BACKGROUND

### TECHNICAL FIELD

The present invention relates to a light-emitting diode (LED) display device.

### DESCRIPTION OF RELATED ART

Light Emitting Diode (LED) display devices, particularly micro-LED display devices, have the advantage of high resolution. The micro-LEDs in the display device are disposed in pixels and used to display fine display images. Generally, a driving chip is used to control the current and signals for operating the micro-LEDs.

Chip on film (COF) package technology is a thin film packaging method, mainly used to package driving chips on a flexible substrate and set them in the peripheral area of the display panel. The chip on film package structure may be bent to the back of the display panel, thereby saving the border size of the display device. The driving chip is connected to the micro-LED components in the display panel through COF technology and is used to output signals to the micro-LEDs, ensuring the precise operation of the display device.

### SUMMARY

The present invention provides an LED display device, which may reduce the cost required for the chip on film package structure.

At least one embodiment of the present invention provides an LED display device, which includes an LED display panel and a first chip on film package structure. The first chip on film package structure is bonded to the LED display panel, and includes a first chip, a second chip, and a first circuit board. The first chip includes a plurality of first signal output bumps and a plurality of first dummy bumps. The second chip includes a plurality of second signal output bumps. The first circuit board includes a plurality of first signal output lines and a plurality of second signal output lines. The first signal output lines are respectively electrically connected to the first signal output bumps. The second signal output lines are respectively electrically connected to the second signal output bumps. At least a part of the second signal output lines are respectively electrically connected to the first dummy bumps. One of the first chip and the second chip is a light-emitting signal control chip.

At least one embodiment of the present invention provides an LED display device, which includes an LED display panel and a chip on film package structure. The first chip on film package structure is bonded to the LED display panel, and includes an integrated chip and a circuit board. The integrated chip includes a first circuit and a second circuit. The first circuit is a light-emitting signal control circuit. The second circuit is a gate signal control circuit, a data signal control circuit or a reset signal control circuit. The circuit board includes a plurality of first signal output lines and a plurality of second signal output lines. The first signal output lines are electrically connected to the first circuit. The first circuit outputs light-emitting signals to the first signal output lines. The second signal output lines are electrically connected to the second circuit. The second circuit outputs gate signals, data signals or reset signals to the second signal output lines.

### BRIEF DESCRIPTION OF THE DRAWINGS

FIG. 1A is a top view illustrating an LED display device according to an embodiment of the present invention.

FIG. 1B is a top view illustrating the first chip on film package structure of FIG. 1A.

FIG. 1C is a top view illustrating the first chip and the second chip in the first chip on film package structure of FIG. 1B.

FIG. 1D is a top view illustrating the second chip on film package structure of FIG. 1A.

FIG. 1E is a top view illustrating the third chip and the fourth chip in the second chip on film package structure of FIG. 1D.

FIG. 1F is a top view illustrating the third chip on film package structure of FIG. 1A.

FIG. 1G is a top view illustrating the fifth chip and the sixth chip in the third chip on film package structure of FIG. 1F.

FIG. 2A is a top view illustrating an LED display device according to an embodiment of the invention.

FIG. 2B is a top view illustrating the first chip on film package structure of FIG. 2A.

FIG. 2C is a top view illustrating the first chip and the second chip in the first chip on film package structure of FIG. 2B.

FIG. 2D is a top view illustrating the second chip on film package structure of FIG. 2A.

FIG. 2E is a top view illustrating the third chip and the fourth chip in the second chip on film package structure of FIG. 2D.

FIG. 2F is a top view illustrating the third chip on film package structure of FIG. 2A.

FIG. 2G is a top view illustrating the fifth chip and the sixth chip in the third chip on film package structure of FIG. 2F.

FIG. 3A is a top view illustrating an LED display device according to an embodiment of the invention.

FIG. 3B is a top view illustrating the chip on film package structure of FIG. 3A.

FIG. 4 is a top view illustrating an LED display panel and a chip on film package structure according to an embodiment of the invention.

FIG. 5 is a top view illustrating an LED display panel and a chip on film package structure according to an embodiment of the invention.

FIG. 6 is a partial top view illustrating a chip on film package structure according to an embodiment of the invention.

FIG. 7 is a partial top view illustrating a chip on film package structure according to an embodiment of the invention.

FIG. 8 is a partial top view illustrating a chip on film package structure according to an embodiment of the invention.

FIG. 9A is a circuit diagram illustrating a pixel structure according to an embodiment of the invention.

FIG. 9B is a timing diagram of signals for operating a pixel structure according to an embodiment of the invention.

FIG. 10 is a top view illustrating a first chip and a second chip in a first chip on film package structure according to another embodiment of the invention.

FIG. 11 is a top view illustrating a first chip and a second chip in a first chip on film package structure according to another embodiment of the invention.

### DESCRIPTION OF THE EMBODIMENTS

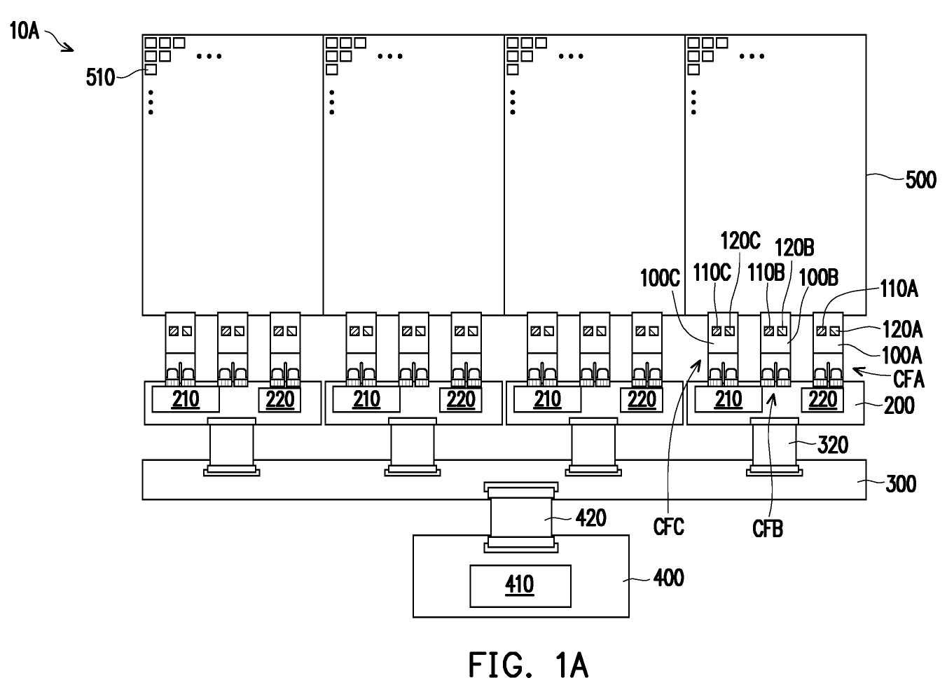

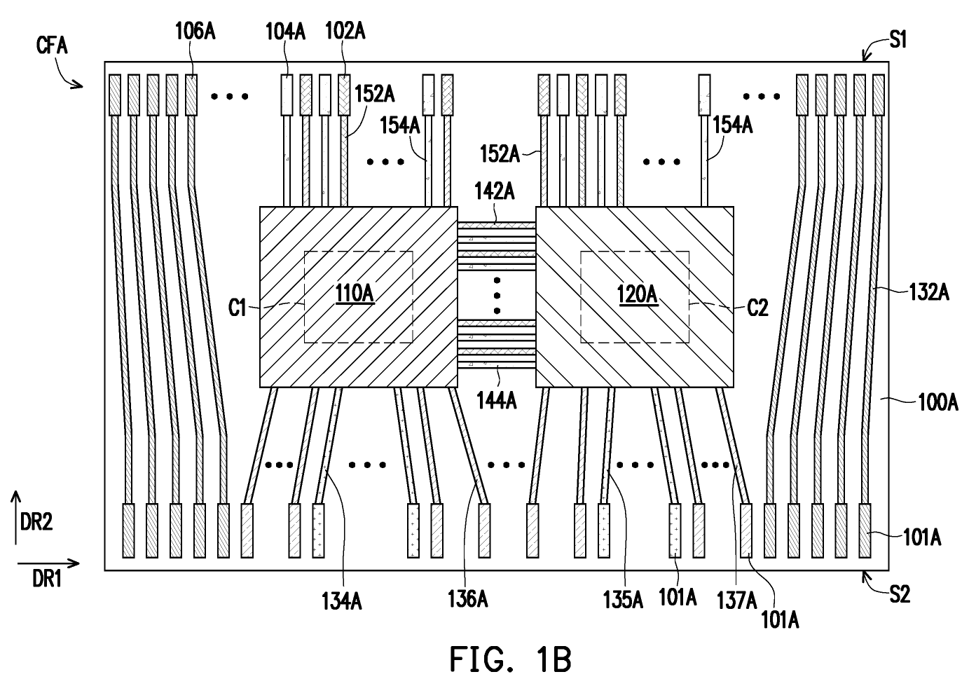

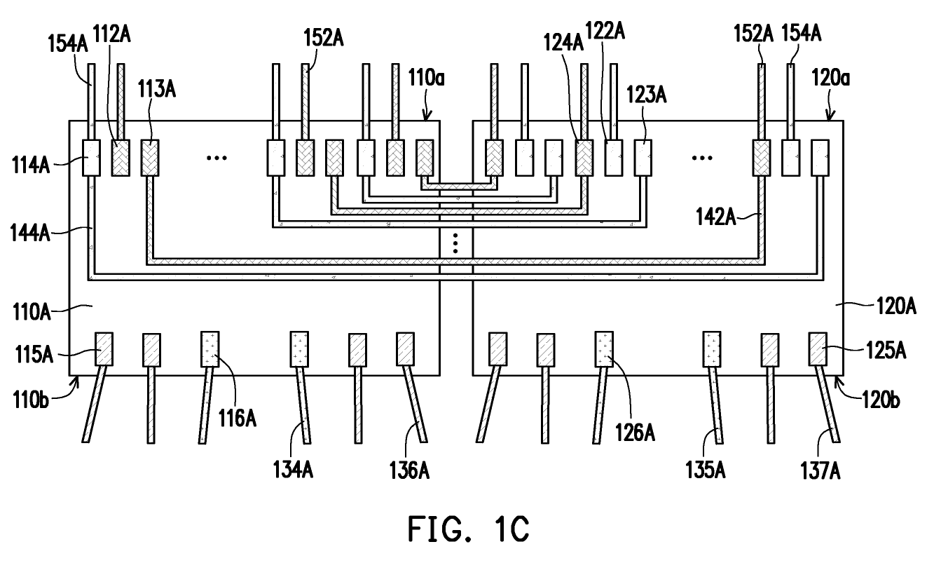

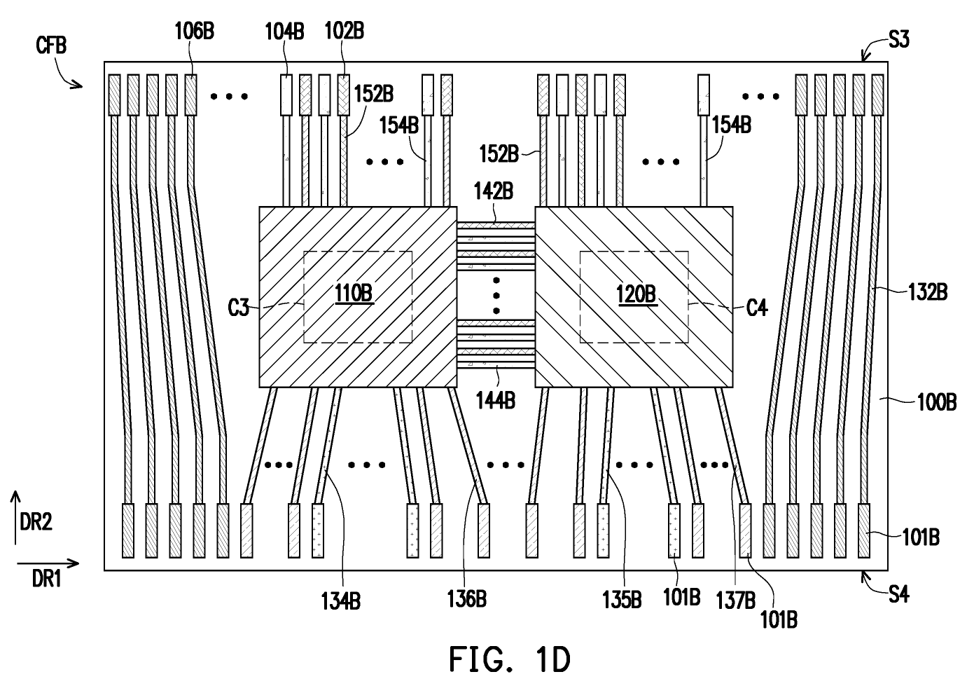

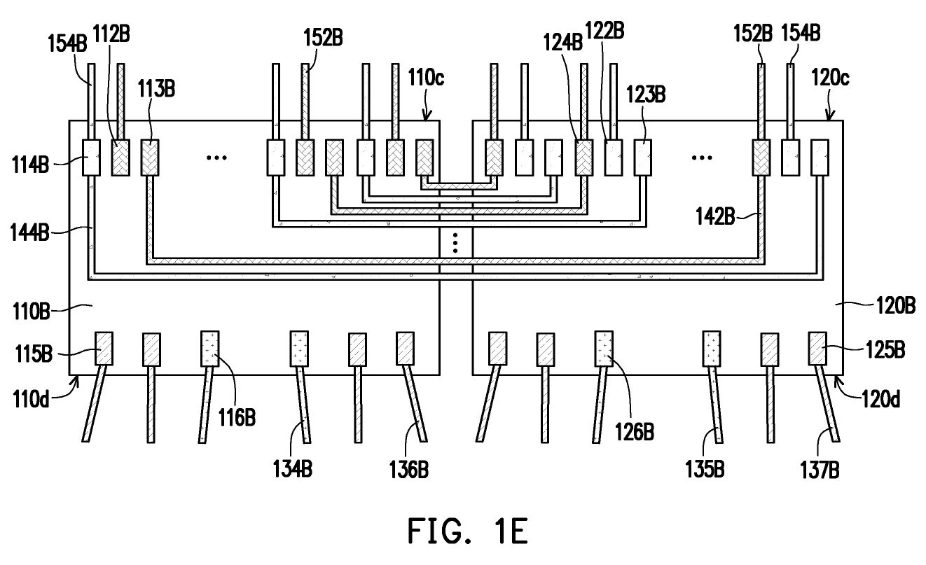

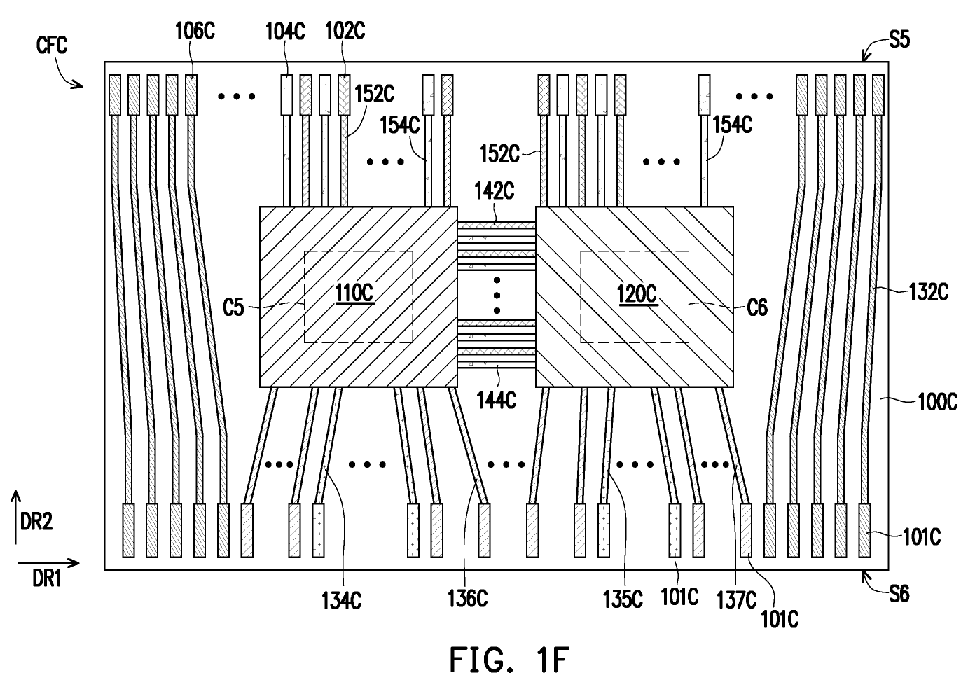

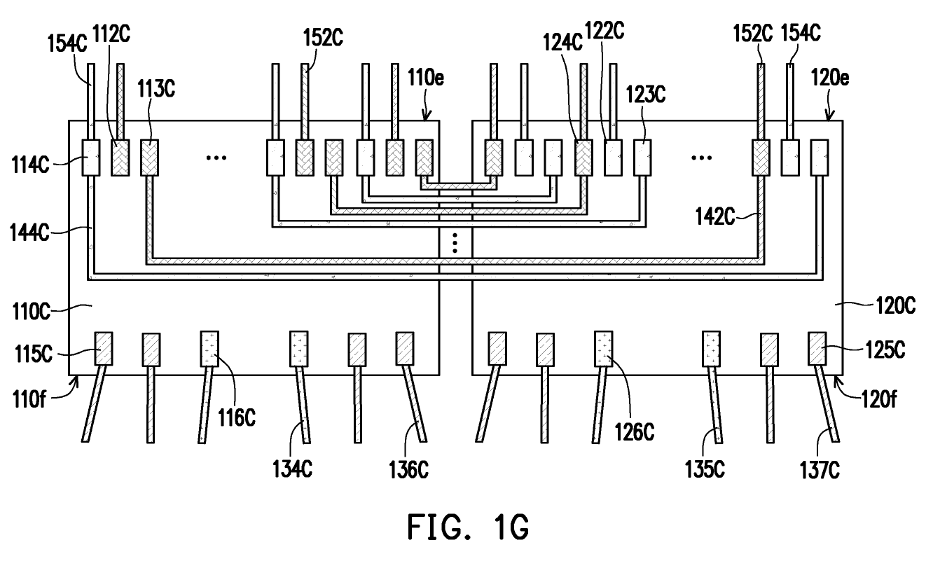

FIG. 1A is a top view illustrating an LED display device 10A according to an embodiment of the invention. Referring to FIG. 1A, the LED display device 10A is a tiled display device, and includes multiple LED display panels 500 tiled together. Each LED display panel 500 includes multiple pixel structures 510 arranged in an array, and each pixel structure 510 includes a pixel circuit and a corresponding LED.

In some embodiments, each LED display panel 500 is electrically connected to a first chip on film package structure CFA, a second chip on film package structure CFB, and a third chip on film package structure CFC. For example, the first chip on film package structure CFA, the second chip on film package structure CFB, and the third chip on film package structure CFC are bonded to the peripheral area of the LED display panel 500. The first chip on film package structure CFA, the second chip on film package structure CFB, and the third chip on film package structure CFC may have the same or different structures. Although in FIG. 1A each LED display panel 500 is electrically connected to three chip on film package structures, the invention is not limited thereto. Each LED display panel 500 may be electrically connected to more or fewer chip on film package structures.

Each LED display panel 500 is electrically connected to a first circuit board 200 through the first chip on film package structure CFA, the second chip on film package structure CFB, and the third chip on film package structure CFC. In some embodiments, the first circuit board 200 includes a power integrated circuit (IC) 210 and a memory IC 220. For example, the power IC 210 and the memory IC 220 are disposed in different chips, respectively, and these chips are bonded to the first circuit board 200.

Multiple first circuit boards 200 are electrically connected to a second circuit board 300 through multiple flexible circuit boards 320. The second circuit board 300 is electrically connected to a third circuit board 400 through a flexible circuit board 420. In some embodiments, a timing controller IC 410 is incorporated on the third circuit board 400. In some embodiments, the timing controller IC 410 is disposed in a chip, and the chip is bonded to the third circuit board 400.

Referring to FIG. 1A, FIG. 1B and FIG. 1C, the first chip on film package structure CFA includes a first circuit board 100A, a first chip 110A and a second chip 120A. The first circuit board 100A is, for example, a flexible circuit board, and includes multiple input pads 101A, multiple first signal output pads 102A, multiple second signal output pads 104A, multiple power transmission pads 106A, multiple power transmission lines 132A, multiple first power supply lines 136A, multiple second power supply lines 137A, multiple first signal input lines 134A, multiple second signal input lines 135A, multiple first connection lines 142A, multiple second connection lines 144A, multiple first signal output lines 152A and multiple second signal output lines 154A. In some embodiments, the first circuit board 100A includes a flexible substrate and multiple conductive layers and multiple insulation layers disposed on the flexible substrate, and the aforementioned pads, power transmission lines, power supply lines, signal input lines, connection lines and signal output lines may be distributed in the same or different conductive layers.

The first signal output pads 102A, the second signal output pads 104A and the power transmission pads 106A are arranged along a first side S1 of the first chip on film package structure CFA, and are bonded to the LED display panel 500. For example, the first signal output pads 102A, the second signal output pads 104A and the power transmission pads 106A are arranged along a first direction DR1 at a position approaching the first side S1.

The input pads 101A are arranged along a second side S2 of the first chip on film package structure CFA opposite to the first side S1, and are bonded to the first circuit board 200. For example, the input pads 101A are arranged along the first direction DR1 at a position approaching the second side S2.

The power transmission lines 132A connect the power transmission pads 106A to corresponding input pads 101A. For example, power signals are transmitted to the LED display panel 500 through corresponding input pads 101A, power transmission lines 132A and power transmission pads 106A, and further transmitted to corresponding pixel structures 510.

The first chip 110A and the second chip 120A are bonded to the first circuit board 100A. In this embodiment, the arrangement direction of the first chip 110A and the second chip 120A is staggered with a virtual line extending between the first side S1 and the second side S2 (for example, a virtual line parallel to the second direction DR2). In some embodiments, the second direction DR2 may be perpendicular to the first direction DR1. In some embodiments, the first chip 110A and the second chip 120A are arranged along the first direction DR1.

Referring to FIG. 1B and FIG. 1C, the first chip 110A includes multiple first signal output bumps 112A, 113A, multiple first dummy bumps 114A, multiple first power input bumps 115A and multiple first signal input bumps 116A. The second chip 120A includes multiple second signal output bumps 122A, 123A, multiple second dummy bumps 124A, multiple second power input bumps 125A and multiple second signal input bumps 126A. In some embodiments, the first signal output bumps 112A, 113A and the first dummy bumps 114A are disposed in a staggered manner, while the second signal output bumps 122A, 123A and the second dummy bumps 124A are disposed in a staggered manner. The quantity of the first signal output bumps 112A, 113A and the first dummy bumps 114A may be adjusted according to requirements. In some embodiments, the total number of the first signal output bumps 112A, 113A may be greater than or equal to the total number of the first dummy bumps 114A. Similarly, the quantity of the second signal output bumps 122A, 123A and the second dummy bumps 124A may be adjusted according to requirements. In some embodiments, the total number of the second signal output bumps 122A, 123A may be greater than or equal to the total number of the second dummy bumps 124A.

In some embodiments, the first signal output bumps 112A, 113A and the first dummy bumps 114A are arranged along a first side 110a of the first chip 110A, while the first power input bumps 115A and the first signal input bumps 116A are arranged along a second side 110b of the first chip 110A opposite to the first side 110a. In some embodiments, the second signal output bumps 122A, 123A and the second dummy bumps 124A are arranged along a first side 120a of the second chip 120A, while the second power input bumps 125A and the second signal input bumps 126A are arranged along a second side 120b of the second chip 120B opposite to the first side 120a.

In this embodiment, the first signal output lines 152A are electrically connected to the first signal output bumps 112A, 113A respectively. Specifically, the first chip 110A outputs signals via the first signal output bumps 112A, 113A, and transmits signals through the first signal output lines 152A to the first signal output pads 102A electrically connected thereto. In this embodiment, the first connection lines 142A extend from the second dummy bumps 124A to at least a part of the first signal output bumps (i.e., the first signal output bumps 113A) respectively. The first signal output bumps 113A are connected to the second dummy bumps 124A through the first connection lines 142A, and thereby electrically connected to the corresponding first signal output lines 152A through the second dummy bumps 124A. In this embodiment, some of the first signal output lines 152A are electrically connected to the first signal output bumps 112A respectively, and extend outward from the first signal output bumps 112A of the first chip 110A; another part of the first signal output lines 152A are electrically connected to the second dummy bumps 124A respectively, and extend outward from the second dummy bumps 124A of the second chip 120A.

The first power input bumps 115A and the first signal input bumps 116A are electrically connected to the first power supply lines 136A and the first signal input lines 134A respectively.

In this embodiment, the second signal output lines 154A are electrically connected to the second signal output bumps 122A, 123A respectively. Specifically, the second chip 120A outputs signals via the second signal output bumps 122A, 123A, and transmits signals through the second signal output lines 154A to the second signal output pads 104A electrically connected thereto. In this embodiment, the second connection lines 144A extend from the first dummy bumps 114A to at least a part of the second signal output bumps (i.e., the second signal output bumps 123A) respectively. The second signal output bumps 123A are electrically connected to the first dummy bumps 114A through the second connection lines 144A, and thereby connected to the corresponding second signal output lines 154A through the first dummy bumps 114A. In this embodiment, part of the second signal output lines 154A are electrically connected to the second signal output bumps 122A respectively, and extend outward from the second signal output bumps 122A of the second chip 120A; another part of the second signal output lines 154A are electrically connected to the first dummy bumps 114A respectively, and extend outward from the first dummy bumps 114A of the first chip 110A.

The second power input bumps 125A and the second signal input bumps 126A are electrically connected to the second power supply lines 137A and the second signal input lines 135A respectively.

In some embodiments, one of the first chip 110A and the second chip 120A may be a light-emitting signal control chip, while the other may be a gate signal control chip, a data signal control chip, or a reset signal control chip. For example, the first chip 110A may be a light-emitting signal control chip. The first circuit C1 in the first chip 110A may be a light-emitting signal control circuit, while the second circuit C2 in the second chip 120A may be a gate signal control circuit, a data signal control circuit, or a reset signal control circuit. In some embodiments, the first circuit C1 (e.g., the light-emitting signal control circuit) may be electrically connected to the first signal output bumps 112A, 113A, and the first dummy bumps 114A may be independent of the first circuit C1. In some embodiments, the second circuit C2 may be electrically connected to the second signal output bumps 122A, 123A, and the second dummy bumps 124A may be independent of the second circuit C2.

In some embodiments, the clock control signals output by the timing controller IC 410 (referring to FIG. 1A) may be transmitted to the first chip 110A through the first signal input lines 134A and the first signal input bumps 116A.

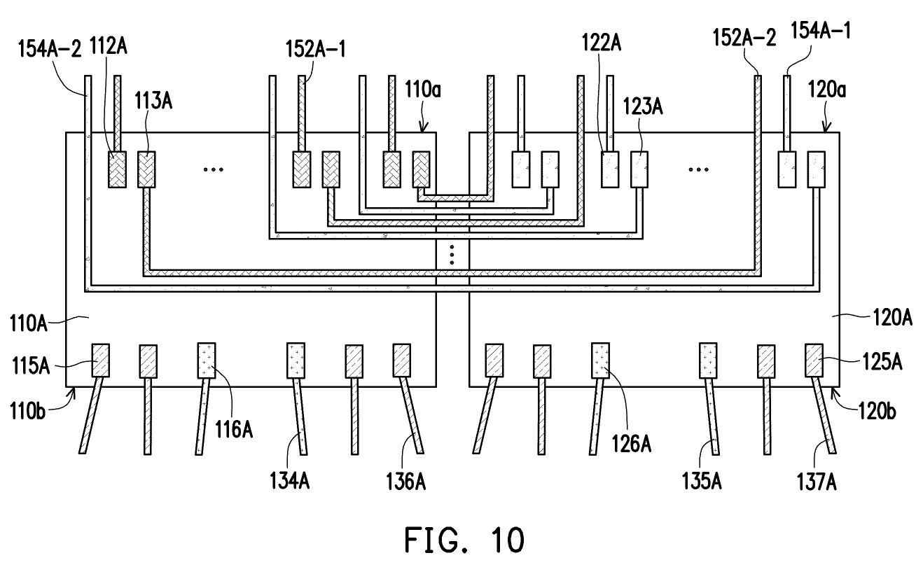

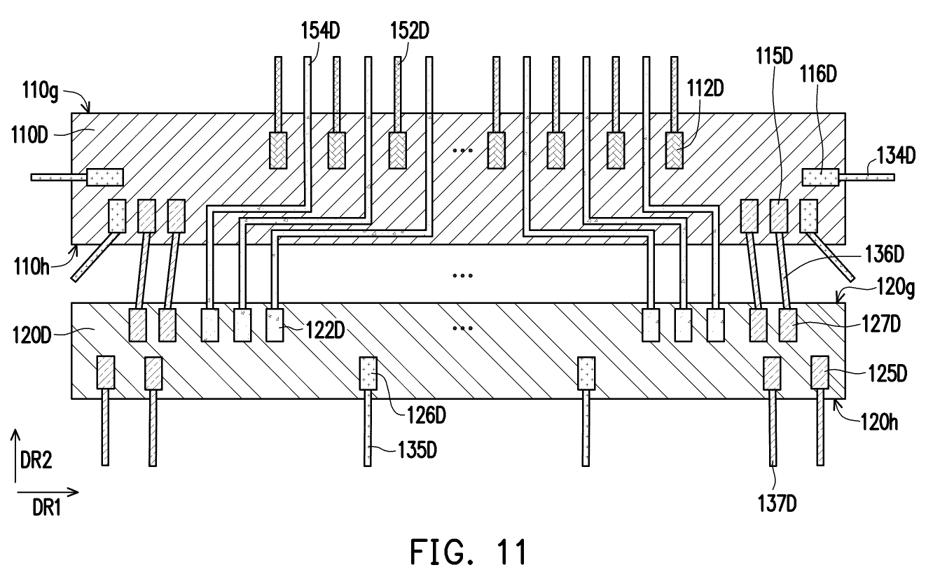

In FIG. 1C, the first chip 110A includes the first dummy bumps 114A, and the second chip 120A includes the second dummy bumps 124A, but the present invention is not limited thereto. In other embodiments, some or all of the first dummy bumps 114A and some or all of the second dummy bumps 124A may be omitted, and some or all of the first connection lines 142A and some or all of the second connection lines 144A may also be omitted, as shown in FIG. 10. Referring to FIG. 10, the first chip on film package structure includes the first signal output lines 152A-1,152A-2 and the second signal output lines 154A-1, 154A-2. The first signal output line 152A-1 is electrically connected to the first signal output bump 112A, while the first signal output line 152A-2 is electrically connected to the first signal output bump 113A.

In the embodiment of FIG. 10, at least part of the first signal output lines (e.g., the first signal output line 152A-1) may extend outward from the first signal output bump 112A and may not overlap with the second chip 120A. At least part of the first signal output lines (e.g., the first signal output line 152A-2) may extend from the first signal output bump 113A towards the second chip 120A, and extend from beneath one side of the second chip 120A (e.g., the left side of the second chip 120A in FIG. 10) to beneath the second chip 120A, and extend beyond the second chip 120A from beneath another side of the second chip 120A (e.g., the first side 120a in FIG. 10). In this embodiment, the first signal output lines 152A-2 partially overlap with the second chip 120A.

On the other hand, in the embodiment of FIG. 10, at least part of the second signal output lines (e.g., the second signal output line 154A-1) may extend outward from the second signal output bump 122A and may not overlap with the first chip 110A. At least part of the second signal output lines (e.g., the second signal output line 154A-2) may extend from the second signal output bump 123A towards the first chip 110A, and extend from beneath one side of the first chip 110A (e.g., the right side of the first chip 110A in FIG. 10) to beneath the first chip 110A, and extend beyond the first chip 110A from beneath another side of the first chip 110A (e.g., the first side 110a in FIG. 10). In this embodiment, the second signal output line 154A-2 partially overlaps with the first chip 110A. Referring to FIG. 1A, FIG. 1D and FIG. 1E, the second chip on film package structure CFB may include a second circuit board 100B, a third chip 110B and a fourth chip 120B. The third circuit board 100B may be, for example, a flexible circuit board, and may include multiple input pads 101B, multiple third signal output pads 102B, multiple fourth signal output pads 104B, multiple power transmission pads 106B, multiple power transmission lines 132B, multiple third power supply lines 136B, multiple fourth power supply lines 137B, multiple third signal input lines 134B, multiple fourth signal input lines 135B, multiple third connection lines 142B, multiple fourth connection lines 144B, multiple third signal output lines 152B and multiple fourth signal output lines 154B. In some embodiments, the second circuit board 100B may include a flexible substrate and multiple conductive layers and multiple insulation layers set on the flexible substrate, and the aforementioned pads, power transmission lines, power supply lines, signal input lines, connection lines and signal output lines may be distributed in the same or different conductive layers.

In some embodiments, the third signal output pads 102B, the fourth signal output pads 104B and the power transmission pads 106B may be arranged along a first direction DR1 at a location approaching the first side S3, and may be bonded to the LED display panel 500.

The input pads 101B may be arranged along the first direction DR1 at a location approaching the second side S4, and may be bonded to the first circuit board 200.

The power transmission lines 132B may connect the power transmission pads 106B to corresponding input pads 101B. For example, power signals may be transmitted to the LED display panel 500 through corresponding input pads 101B, power transmission lines 132B and power transmission pads 106B, and may be further transmitted to corresponding pixel structures 510.

The third chip 110B and the fourth chip 120B may be bonded to the second circuit board 100B. In some embodiments, the third chip 110B and the fourth chip 120B may be arranged along the first direction DR1.

Referring to FIG. 1D and FIG. 1E, the third chip 110B may include multiple third signal output bumps 112B, 113B, multiple third dummy bumps 114B, multiple third power input bumps 115B and multiple third signal input bumps 116B. The fourth chip 120B may include multiple fourth signal output bumps 122B, 123B, multiple fourth dummy bumps 124B, multiple fourth power input bumps 125B and multiple fourth signal input bumps 126B. In some embodiments, the third signal output bumps 112B, 113B and the third dummy bumps 114B may be staggered, while the fourth signal output bumps 122B, 123B and the fourth dummy bumps 124B may be interlaced.

In some embodiments, the third signal output bumps 112B, 113B and the third dummy bumps 114B may be arranged along a first side 110c of the third chip 110B, while the third power input bumps 115B and the third signal input bumps 116B may be arranged along a second side 110d of the third chip 110B opposite to the first side 110c. In some embodiments, the fourth signal output bumps 122B, 123B and the fourth dummy bumps 124B may be arranged along a first side 120c of the fourth chip 120B, while the fourth power input bumps 125B and the fourth signal input bumps 126B may be arranged along a second side 120d of the fourth chip 120B opposite to the first side 120c.

The third chip 110B may output signals via the third signal output bumps 112B, 113B, and may transmit signals through the third signal output lines 152B to the third signal output pads 102B electrically connected thereto. In this embodiment, the third connection lines 142B may extend from the fourth dummy bumps 124B to at least a portion of the third signal output bumps (i.e., the third signal output bumps 113B). The third signal output bumps 113B may be connected to the fourth dummy bumps 124B through the third connection lines 142B, and may be further electrically connected to corresponding third signal output lines 152B through the fourth dummy bumps 124B.

The third power input bumps 115B and the third signal input bumps 116B may be electrically connected to the third power supply lines 136B and the third signal input lines 134B, respectively.

The fourth chip 120B may output signals via the fourth signal output bumps 122B, 123B, and may transmit signals through the fourth signal output lines 154B to the fourth signal output pads 104B electrically connected thereto. In this embodiment, the fourth connection lines 144B may extend from the third dummy bumps 114B to at least a portion of the fourth signal output bumps (i.e., the fourth signal output bumps 123B). The fourth signal output bumps 123B may be electrically connected to the third dummy bumps 114B through the fourth connection lines 144B, and may be further connected to corresponding fourth signal output lines 154B through the third dummy bumps 114B.

The fourth power input bumps 125B and the fourth signal input bumps 126B may be electrically connected to the fourth power supply lines 137B and the fourth signal input lines 135B, respectively.

In some embodiments, the third chip 110B and the fourth chip 120B may be any two combinations of light-emitting signal control chip, gate signal control chip, data signal control chip, and reset signal control chip. For example, the third chip 110B may be a gate signal control chip. The third circuit C3 in the third chip 110B may be a gate signal control circuit, and the fourth circuit C4 in the fourth chip 120B may be a data signal control circuit. In some embodiments, the third circuit C3 may be electrically connected to the third signal output bumps 112B, 113B, and the third dummy bumps 114B may be independent of the third circuit C3. In some embodiments, the fourth circuit C4 may be electrically connected to the fourth signal output bumps 122B, 123B, and the fourth dummy bumps 124B may be independent of the fourth circuit C4.

In some embodiments, the clock control signals output by the timing controller IC 410 (referring to FIG. 1A) may be transmitted to the third chip 110B through the third signal input lines 134B and the third signal input bumps 116B.

Referring to FIG. 1A, FIG. 1F and FIG. 1G, the third chip on film package structure CFC may include a third circuit board 100C, a fifth chip 110C and a sixth chip 120C. The fifth circuit board 100C may be, for example, a flexible circuit board, and may include a plurality of input pads 101C, a plurality of fifth signal output pads 102C, a plurality of sixth signal output pads 104C, a plurality of power transmission pads 106C, a plurality of power transmission lines 132C, a plurality of fifth power supply lines 136C, a plurality of sixth power supply lines 137C, a plurality of fifth signal input lines 134C, a plurality of sixth signal input lines 135C, a plurality of fifth connection lines 142C, a plurality of sixth connection lines 144C, a plurality of fifth signal output lines 152C and a plurality of sixth signal output lines 154C. In some embodiments, the second circuit board 100C may include a flexible substrate and a plurality of conductive layers and a plurality of insulation layers disposed on the flexible substrate, and the aforementioned pads, power transmission lines, power supply lines, signal input lines, connection lines and signal output lines may be distributed in the same or different conductive layers.

In some embodiments, the fifth signal output pads 102C, the sixth signal output pads 104C and the power transmission pads 106C may be arranged along the first direction DR1 at a location approaching the first side S5, and may be bonded to the LED display panel 500.

The input pads 101C may be arranged along the first direction DR1 at a location approaching the second side S6, and may be bonded to the first circuit board 200.

The power transmission lines 132C may connect the power transmission pads 106C to corresponding input pads 101C. For example, the power signals may be transmitted to the LED display panel 500 through the corresponding input pads 101C, power transmission lines 132C and power transmission pads 106C, and may be further transmitted to the corresponding pixel structures 510.

The fifth chip 110C and the sixth chip 120C may be bonded to the second circuit board 100C. In some embodiments, the fifth chip 110C and the sixth chip 120C may be arranged along the first direction DR1.

Referring to FIG. 1F and FIG. 1G, the fifth chip 110C may include a plurality of fifth signal output bumps 112C, 113C, a plurality of fifth dummy bumps 114C, a plurality of fifth power input bumps 115C and a plurality of fifth signal input bumps 116C. The sixth chip 120C may include a plurality of sixth signal output bumps 122C, 123C, a plurality of sixth dummy bumps 124C, a plurality of sixth power input bumps 125C and a plurality of sixth signal input bumps 126C. In some embodiments, the fifth signal output bumps 112C, 113C and the fifth dummy bumps 114C may be staggered, while the sixth signal output bumps 122C, 123C and the sixth dummy bumps 124C may be staggered.

In some embodiments, the fifth signal output bumps 112C, 113C and the fifth dummy bumps 114C may be arranged along a first side 110e of the fifth chip 110C, while the fifth power input bumps 115C and the fifth signal input bumps 116C may be arranged along a second side 110f of the fifth chip 110C opposite to the first side 110e. In some embodiments, the sixth signal output bumps 122C, 123C and the sixth dummy bumps 124C may be arranged along a first side 120e of the sixth chip 120C, while the sixth power input bumps 125C and the sixth signal input bumps 126C may be arranged along a second side 120f of the sixth chip 120C opposite to the first side 120e.

The fifth chip 110C may output signals via the fifth signal output bumps 112C, 113C, and transmit signals through the fifth signal output lines 152C to the fifth signal output pads 102C electrically connected thereto. In this embodiment, the fifth connection lines 142C may extend from the sixth dummy bumps 124C to at least a portion of the fifth signal output bumps (i.e., the fifth signal output bumps 113C). The fifth signal output bumps 113C may be connected to the sixth dummy bumps 124C through the fifth connection lines 142C, and may be further electrically connected to the corresponding fifth signal output lines 152C through the sixth dummy bumps 124C.

The fifth power input bumps 115C and the fifth signal input bumps 116C may be electrically connected to the fifth power supply lines 136C and the fifth signal input lines 134C, respectively.

The sixth chip 120C may output signals via the sixth signal output bumps 122C, 123C, and transmit signals through the sixth signal output lines 154C to the sixth signal output pads 104C electrically connected thereto. In this embodiment, the sixth connection lines 144C may extend from the fifth dummy bumps 114C to at least a portion of the sixth signal output bumps (i.e., the sixth signal output bumps 123C). The sixth signal output bumps 123C may be electrically connected to the fifth dummy bumps 114C through the sixth connection lines 144C, and may be further connected to the corresponding sixth signal output lines 154C through the fifth dummy bumps 114C.

The sixth power input bumps 125C and the sixth signal input bumps 126C may be electrically connected to the sixth power supply lines 137C and the sixth signal input lines 135C, respectively.

In some embodiments, the fifth chip 110C and the sixth chip 120C may be any two combinations of light-emitting signal control chip, gate signal control chip, data signal control chip, and reset signal control chip. For example, the fifth chip 110C may be a reset signal control chip. The fifth circuit C5 in the fifth chip 110C may be a reset signal control circuit, and the sixth circuit C6 in the sixth chip 120C may be a data signal control circuit. In some embodiments, the fifth circuit C5 may be electrically connected to the fifth signal output bumps 112C, 113C, and the fifth dummy bumps 114C may be independent of the fifth circuit C5. In some embodiments, the sixth circuit C6 may be electrically connected to the sixth signal output bumps 122C, 123C, and the sixth dummy bumps 124C may be independent of the sixth circuit C6.

For example, the clock control signal output by the timing controller IC 410 (referring to FIG. 1A) may be transmitted to the fifth chip 110C through the fifth signal input lines 134C and the fifth signal input bumps 116C.

In this embodiment, integrating multiple chips into one chip on film package structure, compared to setting multiple chips separately in different chip on film package structures, may reduce the total number of chip on film package structures, thereby decreasing the quantity and cost of chip on film package structures. As the number of chip on film package structures may be reduced, the border size of the LED display device may be minimized, which in turn may reduce the seam of the tiled display device.

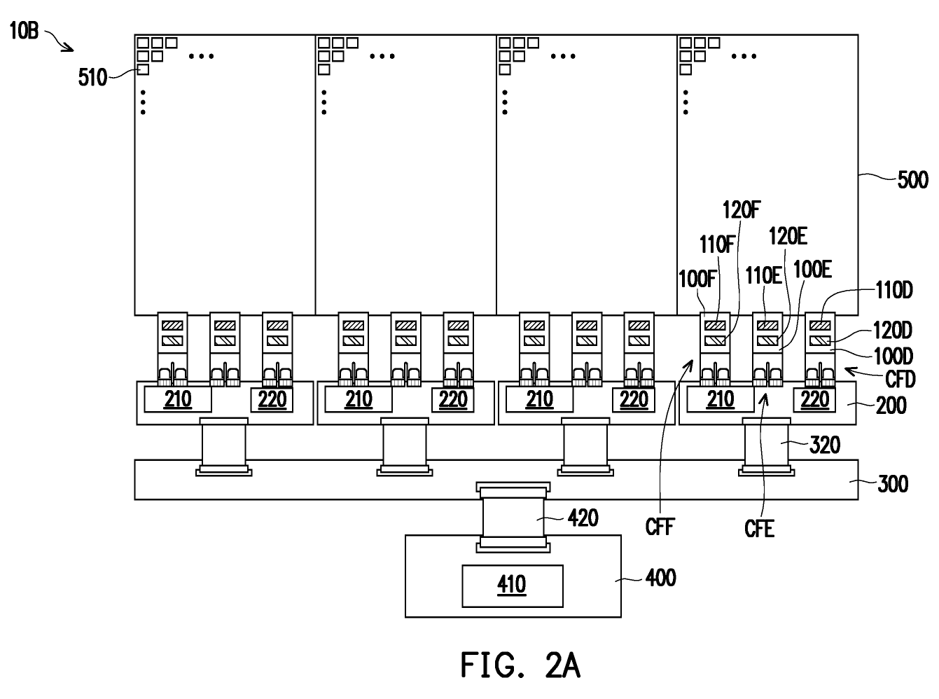

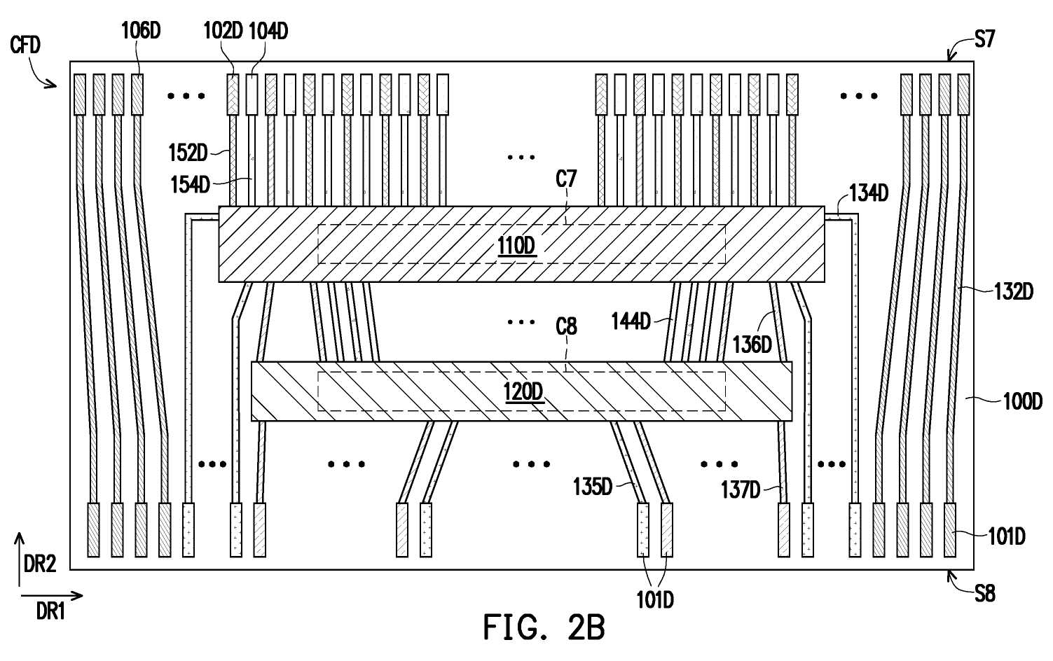

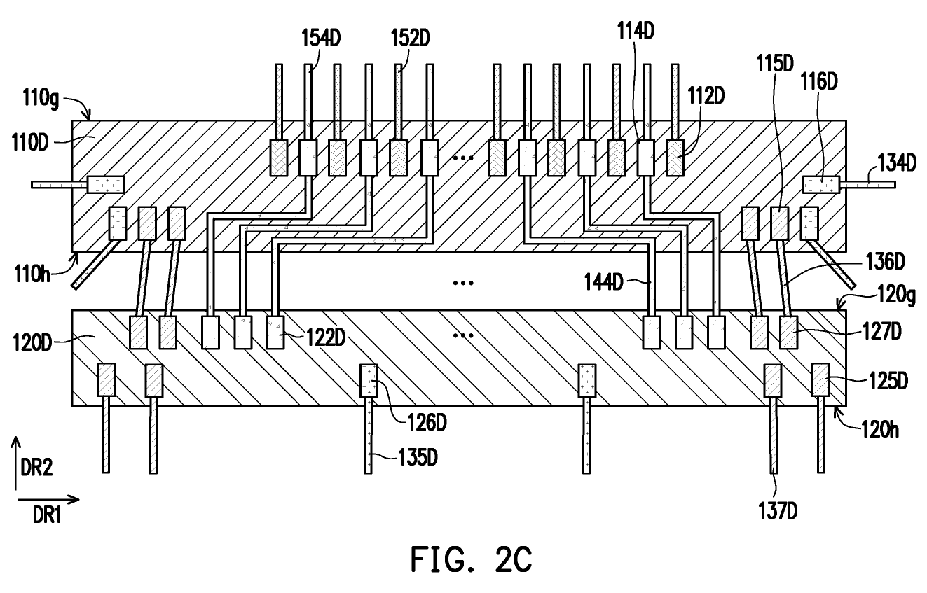

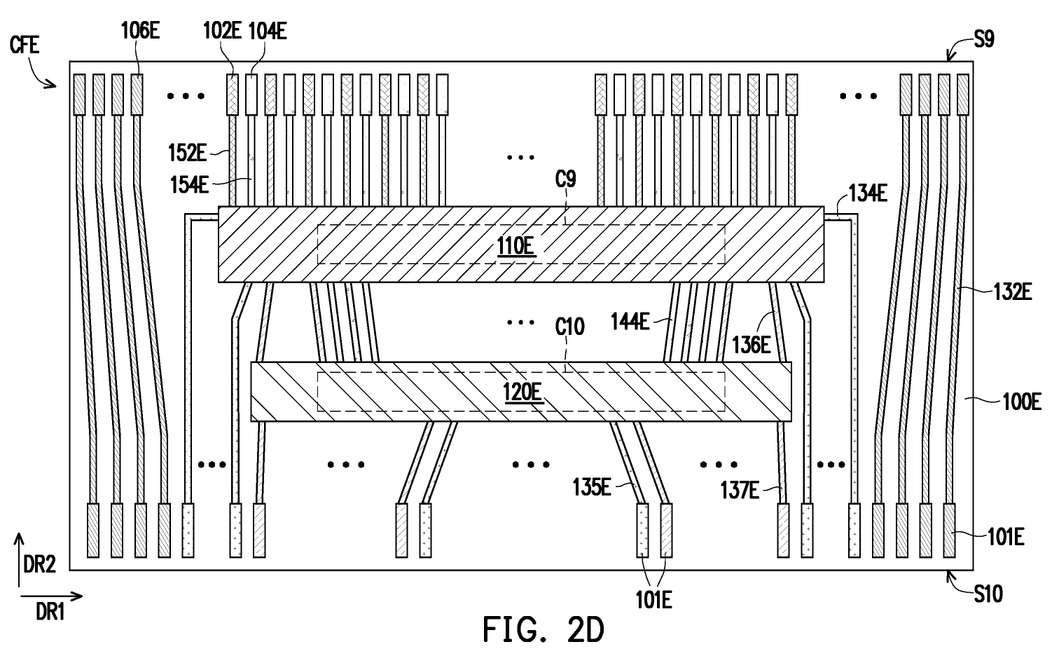

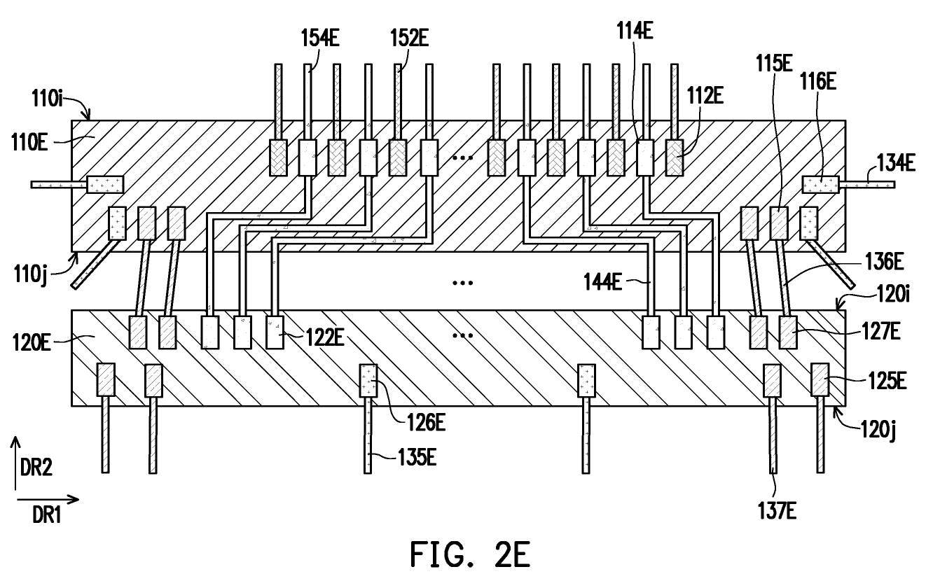

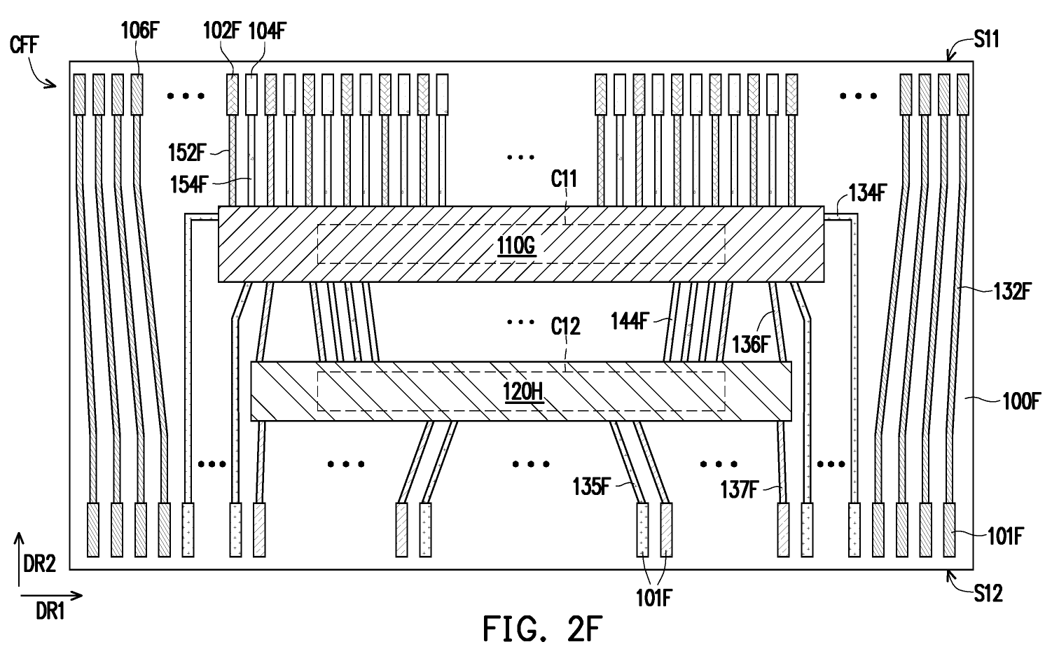

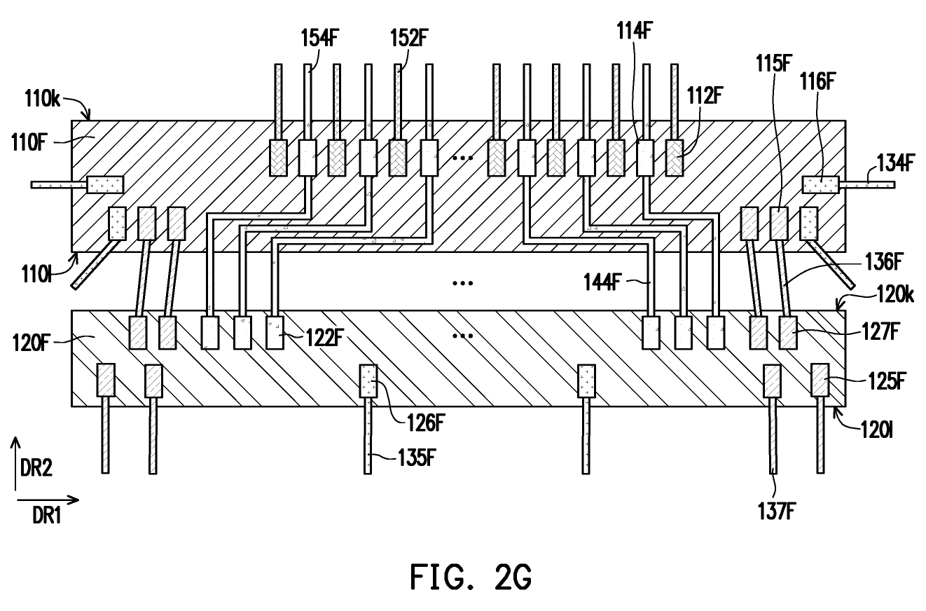

FIG. 2A is a top view illustrating an LED display device 10B according to an embodiment of the invention. Referring to FIG. 2A, the LED display device 10B may be a tiled display device, and may include multiple LED display panels 500 tiled together. Each LED display panel 500 may include multiple pixel structures 510.

In some embodiments, each LED display panel 500 may be electrically connected to a first chip on film package structure CFD, a second chip on film package structure CFE, and a third chip on film package structure CFF. The first chip on film package structure CFD, the second chip on film package structure CFE, and the third chip on film package structure CFF may have the same or different structures. Although in FIG. 2A each LED display panel 500 is electrically connected to three chip on film package structures, the invention is not limited thereto.

Each LED display panel 500 may be electrically connected to the first circuit board 200 through the first chip on film package structure CFD, the second chip on film package structure CFE, and the third chip on film package structure CFF.

Referring to FIG. 2A, FIG. 2B and FIG. 2C, the first chip on film package structure CFD may include a first circuit board 100D, a first chip 110D and a second chip 120D. The first circuit board 100D may be, for example, a flexible circuit board, and may include multiple input pads 101D, multiple first signal output pads 102D, multiple second signal output pads 104D, multiple power transmission pads 106D, multiple power transmission lines 132D, multiple first power supply lines 136D, multiple second power supply lines 137D, multiple first signal input lines 134D, multiple second signal input lines 135D, multiple connection lines 144D, multiple first signal output lines 152D and multiple second signal output lines 154D. In some embodiments, the first circuit board 100D may include a flexible substrate and multiple conductive layers and multiple insulation layers disposed on the flexible substrate, and the aforementioned pads, power transmission lines, power supply lines, signal input lines, connection lines and signal output lines may be distributed in the same or different conductive layers.

The first signal output pads 102D, the second signal output pads 104D and the power transmission pads 106D may be arranged along a first side S7 of the first chip on film package structure CFD, and may be bonded to the LED display panel 500. For example, the first signal output pads 102D, the second signal output pads 104D and the power transmission pads 106D may be arranged along a first direction DR1 at a location approaching the first side S7.

The input pads 101D may be arranged along a second side S8 of the first chip on film package structure CFD opposite to the first side S7, and may be bonded to the first circuit board 200. For example, the input pads 101D may be arranged along the first direction DR1 at a location approaching the second side S8.

The power transmission lines 132D may connect the power transmission pads 106D to corresponding input pads 101D. For example, power signals may be transmitted to the LED display panel 500 through corresponding input pads 101D, power transmission lines 132D and power transmission pads 106D, and may be further transmitted to corresponding pixel structures 510.

The first chip 110D and the second chip 120D may be bonded to the first circuit board 100D. In this embodiment, the arrangement direction of the first chip 110D and the second chip 120D is staggered with a virtual connection line extending between the first side S7 and the second side S8 (for example, a virtual connection line parallel to the second direction DR2). In some embodiments, the second direction DR2 may be perpendicular to the first direction DR1. In some embodiments, the first chip 110D and the second chip 120D may be arranged along the second direction DR2. The first chip 110D may be located between the second chip 120D and the second signal output pads 104D and between the second chip 120D and the first signal output pads 102D.

Referring to FIG. 2B and FIG. 2C, the first chip 110D may include multiple first signal output bumps 112D, multiple first dummy bumps 114D, multiple first power input bumps 115D and multiple first signal input bumps 116D. The second chip 120D may include multiple second signal output bumps 122D, multiple second power input bumps 125D, second signal input bumps 126D and multiple power output bumps 127D. In some embodiments, the first signal output bumps 112D and the first dummy bumps 114D may be disposed in a staggered manner.

In some embodiments, the first signal output bumps 112D and the first dummy bumps 114D may be arranged along a first side 110g of the first chip 110D, while the first power input bumps 115D and part of the first signal input bumps 116D may be arranged along a second side 110h of the first chip 110D opposite to the first side 110g. In some embodiments, the second signal output bumps 122D and the power output bumps 127D may be arranged along a first side 120g of the second chip 120D, while the second power input bumps 125D and the second signal input bumps 126D may be arranged along a second side 120h of the second chip 120D opposite to the first side 120g.

In this embodiment, the first signal output lines 152D may be respectively electrically connected to the first signal output bumps 112D. Specifically, the first chip 110D may output signals via the first signal output bumps 112D, and may transmit signals through the first signal output lines 152D to the first signal output pads 102D electrically connected thereto. In this embodiment, the connection lines 144D may respectively extend from the second signal output bumps 122D to the first dummy bumps 114D, and may be further electrically connected to corresponding second signal output lines 154D through the first dummy bumps 114D.

The first power supply line 136D may electrically connect the power output bumps 127D of the second chip 120D to the first power input bumps 115D of the first chip 110D. The first signal input bumps 116D may be electrically connected to the first signal input lines 134D. The second power input bumps 125D may be electrically connected to the second power supply lines 137D. The second signal input bumps 126D may be electrically connected to the second signal input lines 135D.

In some embodiments, one of the first chip 110D and the second chip 120D may be a light-emitting signal control chip, while the other may be a gate signal control chip, a data signal control chip, or a reset signal control chip. For example, the first chip 110D may be a light-emitting signal control chip. The first circuit C7 in the first chip 110D may be a light-emitting signal control circuit, while the second circuit C8 in the second chip 120D may be a gate signal control circuit, a data signal control circuit, or a reset signal control circuit. In some embodiments, the first circuit C7 (e.g., the light-emitting signal control circuit) may be electrically connected to the first signal output bumps 112D, and the first dummy bumps 114D may be independent of the first circuit C7. In some embodiments, the second circuit C8 may be electrically connected to the second signal output bumps 122D.

In some embodiments, the clock control signal output by the timing controller IC 410 (referring to FIG. 2A) may be transmitted to the first chip 110D through the first signal input lines 134D and the first signal input bumps 116D.

In FIG. 2C, the first chip 110D may include the first dummy bumps 114D, but the present invention is not limited thereto. In other embodiments, some or all of the first dummy bumps 114D may be omitted, and some or all of the connection lines 144D may also be omitted, as shown in FIG. 11. Referring to FIG. 11, in this embodiment, at least part of the second signal output lines 154D may extend from the second signal output bumps 122D towards the first chip 110D, and extend from beneath one side of the first chip 110D (e.g., the second side 110h in FIG. 11) to beneath the first chip 110D, and extend beyond the first chip 110D from beneath another side of the first chip 110D (e.g., the first side 110g in FIG. 11). In this embodiment, the second signal output lines 154D may partially overlap with the first chip 110D.

Referring to FIG. 2A, 2D and 2E, the second chip on film package structure CFE may include a second circuit board 100E, a third chip 110E and a fourth chip 120E. The second circuit board 100E may be, for example, a flexible circuit board, and may include a plurality of input pads 101E, a plurality of third signal output pads 102E, a plurality of fourth signal output pads 104E, a plurality of power transmission pads 106E, a plurality of power transmission lines 132E, a plurality of third power supply lines 136E, a plurality of fourth power supply lines 137E, a plurality of third signal input lines 134E, a plurality of fourth signal input lines 135E, a plurality of connection lines 144E, a plurality of third signal output lines 152E and a plurality of fourth signal output lines 154E. In some embodiments, the second circuit board 100E may include a flexible substrate and multiple conductive layers and multiple insulation layers disposed on the flexible substrate, and the aforementioned pads, power transmission lines, power supply lines, signal input lines, connection lines and signal output lines may be distributed in the same or different conductive layers.

The third signal output pads 102E, the fourth signal output pads 104E and the power transmission pads 106E may be arranged along the first side S9 of the second chip on film package structure CFE, and may be bonded to the LED display panel 500. For example, the third signal output pads 102E, the fourth signal output pads 104E and the power transmission pads 106E may be arranged along the first direction DR1 at a position close to the first side S9.

The input pads 101E may be arranged along the second side S10 of the second chip on film package structure CFE, which is opposite to the first side S9, and may be bonded to the first circuit board 200. For example, the input pads 101E may be arranged along the first direction DR1 at a position close to the second side S10.

The power transmission lines 132E may connect the power transmission pads 106E to corresponding input pads 101E. For example, the power signal may be transmitted to the LED display panel 500 through the corresponding input pads 101E, the power transmission lines 132E and the power transmission pads 106E, and may be further transmitted to the corresponding pixel structures 510.

The third chip 110E and the fourth chip 120E may be bonded to the second circuit board 100E. In this embodiment, the arrangement direction of the third chip 110E and the fourth chip 120E is staggered with a virtual connection line extending between the first side S9 and the second side S10 (for example, a virtual connection line parallel to the second direction DR2). In some embodiments, the second direction DR2 may be perpendicular to the first direction DR1. In some embodiments, the third chip 110E and the fourth chip 120E may be arranged along the second direction DR2. The third chip 110E may be positioned between the fourth chip 120E and the fourth signal output pads 104E, and between the fourth chip 120E and the third signal output pads 102E.

Referring to FIG. 2D and FIG. 2E, the third chip 110E may include a plurality of third signal output bumps 112E, a plurality of third dummy bumps 114E, a plurality of third power input bumps 115E and a plurality of third signal input bumps 116E. The fourth chip 120E may include a plurality of fourth signal output bumps 122E, a plurality of fourth power input bumps 125E, fourth signal input bumps 126E and a plurality of power output bumps 127E. In some embodiments, the third signal output bumps 112E and the third dummy bumps 114E may be disposed in a staggered manner.

In some embodiments, the third signal output bumps 112E and the third dummy bumps 114E may be arranged along the first side 110i of the third chip 110E, while the third power input bumps 115E and part of the third signal input bumps 116E may be arranged along the second side 110j of the third chip 110E, which is opposite to the first side 110i. In some embodiments, the fourth signal output bumps 122E and the power output bumps 127E may be arranged along the first side 120i of the fourth chip 120E, while the fourth power input bumps 125E and the fourth signal input bumps 126E may be arranged along the second side 120j of the fourth chip 120E, which is opposite to the first side 120i.

In this embodiment, the third signal output lines 152E may be respectively electrically connected to the third signal output bumps 112E. Specifically, the third chip 110E may output signals via the third signal output bumps 112E, and may transmit signals through the third signal output lines 152E to the third signal output pads 102E that are electrically connected thereto. In this embodiment, the connection lines 144E may respectively extend from the fourth signal output bumps 122E to the third dummy bumps 114E, and may be further electrically connected to the corresponding fourth signal output lines 154E through the third dummy bumps 114E.

The third power supply lines 136E may electrically connect the power output bumps 127E of the fourth chip 120E to the third power input bumps 115E of the third chip 110E. The third signal input bumps 116E may be electrically connected to the third signal input lines 134E. The fourth power input bumps 125E may be electrically connected to the fourth power supply lines 137E. The fourth signal input bumps 126E may be electrically connected to the fourth signal input lines 135E.

In some embodiments, the third chip 110E and the fourth chip 120E may be any two combinations of light-emitting signal control chip, gate signal control chip, data signal control chip, and reset signal control chip. For example, the third chip 110E may be a gate signal control chip. The third circuit C9 in the third chip 110E may be a gate signal control circuit, while the fourth circuit C10 in the fourth chip 120E may be a data signal control circuit. In some embodiments, the third circuit C9 may be electrically connected to the third signal output bumps 112E, and the third dummy bumps 114E may be independent of the third circuit C9. In some embodiments, the fourth circuit C10 may be electrically connected to the fourth signal output bumps 122E.

In some embodiments, the clock control signals output by the timing controller IC 410 (referring to FIG. 2A) may be transmitted to the third chip 110E through the third signal input lines 134E and the third signal input bumps 116E.

Please refer to FIG. 2A, 2F and 2G, the third chip on film package structure CFF may include a third circuit board 100F, a fifth chip 110F and a sixth chip 120F. The third circuit board 100F may be, for example, a flexible circuit board, and may include a plurality of input pads 101F, a plurality of fifth signal output pads 102F, a plurality of sixth signal output pads 104F, a plurality of power transmission pads 106F, a plurality of power transmission lines 132F, a plurality of fifth power supply lines 136F, a plurality of sixth power supply lines 137F, a plurality of fifth signal input lines 134F, a plurality of sixth signal input lines 135F, a plurality of connection lines 144F, a plurality of fifth signal output lines 152F and a plurality of sixth signal output lines 154F. In some embodiments, the third circuit board 100F may include a flexible substrate and multiple conductive layers and multiple insulation layers disposed on the flexible substrate, and the aforementioned pads, power transmission lines, power supply lines, signal input lines, connection lines and signal output lines may be distributed in the same or different conductive layers.

The fifth signal output pads 102F, the sixth signal output pads 104F and the power transmission pads 106F may be arranged along a first side S11 of the third chip on film package structure CFF, and may be bonded to the LED display panel 500. For example, the fifth signal output pads 102F, the sixth signal output pads 104F and the power transmission pads 106F may be arranged along a first direction DR1 at a location approaching the first side S11.

The input pads 101F may be arranged along a second side S12 of the third chip on film package structure CFF opposite to the first side S11, and may be bonded to the first circuit board 200. For example, the input pads 101F may be arranged along the first direction DR1 at a location approaching the second side S12.

The power transmission lines 132F may connect the power transmission pads 106F to corresponding input pads 101F. For example, power signals may be transmitted to the LED display panel 500 through corresponding input pads 101F, power transmission lines 132F and power transmission pads 106F, and may be further transmitted to corresponding pixel structures 510.

The fifth chip 110F and the sixth chip 120F may be bonded to the third circuit board 100F. In this embodiment, the arrangement direction of the fifth chip 110F and the sixth chip 120F is staggered with a virtual line extending between the first side S11 and the second side S12 (for example, a virtual line parallel to the second direction DR2). In some embodiments, the second direction DR2 may be perpendicular to the first direction DR1. In some embodiments, the fifth chip 110F and the sixth chip 120F may be arranged along the second direction DR2. The fifth chip 110F may be located between the sixth chip 120F and the sixth signal output pads 104F and between the sixth chip 120F and the fifth signal output pads 102F.

Referring to FIG. 2F and FIG. 2G, the fifth chip 110F may include a plurality of fifth signal output bumps 112F, a plurality of fifth dummy bumps 114F, a plurality of fifth power input bumps 115F and a plurality of fifth signal input bumps 116F. The sixth chip 120F may include a plurality of sixth signal output bumps 122F, a plurality of sixth power input bumps 125F, sixth signal input bumps 126F and a plurality of power output bumps 127F. In some embodiments, the fifth signal output bumps 112F and the fifth dummy bumps 114F may be disposed in a staggered manner.

In some embodiments, the fifth signal output bumps 112F and the fifth dummy bumps 114F may be arranged along a first side 110k of the fifth chip 110F, while the fifth power input bumps 115F and part of the fifth signal input bumps 116F may be arranged along a second side 110l of the fifth chip 110F opposite to the first side 110k. In some embodiments, the sixth signal output bumps 122F and the power output bumps 127F may be arranged along a first side 120k of the sixth chip 120F, while the sixth power input bumps 125F and the sixth signal input bumps 126F may be arranged along a second side 120l of the sixth chip 120F opposite to the first side 120k.

In this embodiment, the fifth signal output lines 152F may be respectively electrically connected to the fifth signal output bumps 112F. Specifically, the fifth chip 110F may output signals via the fifth signal output bumps 112F, and may transmit signals through the fifth signal output lines 152F to the fifth signal output pads 102F electrically connected thereto. In this embodiment, the connection lines 144F may respectively extend from the sixth signal output bumps 122F to the fifth dummy bumps 114F, and may be further electrically connected to corresponding sixth signal output lines 154F through the fifth dummy bumps 114F.

The fifth power supply lines 136F may electrically connect the power output bumps 127F of the sixth chip 120F to the fifth power input bumps 115F of the fifth chip 110F. The fifth signal input bumps 116F may be electrically connected to the fifth signal input lines 134F. The sixth power input bumps 125F may be electrically connected to the sixth power supply lines 137F. The sixth signal input bumps 126F may be electrically connected to the sixth signal input lines 135F.

In some embodiments, the fifth chip 110F and the sixth chip 120F may be ny two combinations of a light-emitting signal control chip, a gate signal control chip, a data signal control chip, and a reset signal control chip. For example, the fifth chip 110F may be a reset signal control chip. The fifth circuit C11 in the fifth chip 110F may be a reset signal control circuit, while the sixth circuit C12 in the sixth chip 120F may be a data signal control circuit. In some embodiments, the fifth circuit C11 may be electrically connected to the fifth signal output bumps 112F, and the fifth dummy bumps 114F may be independent of the fifth circuit C11. In some embodiments, the sixth circuit C12 may be electrically connected to the sixth signal output bumps 122F.

In some embodiments, the clock control signals output by the timing controller IC 410 (referring to FIG. 2A) may be transmitted to the fifth chip 110F through the fifth signal input lines 134F and the fifth signal input bumps 116F.

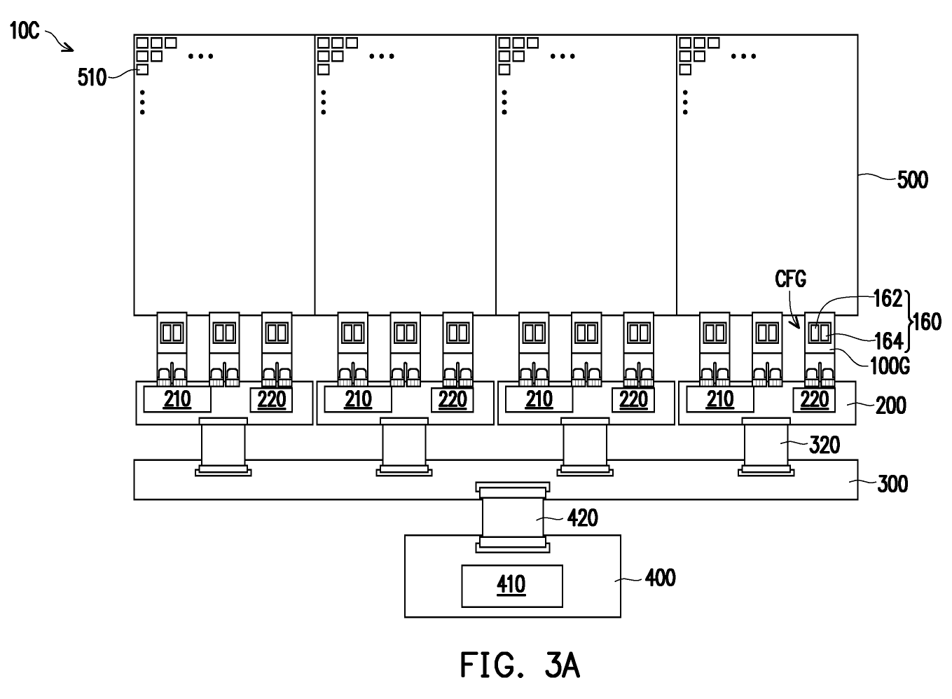

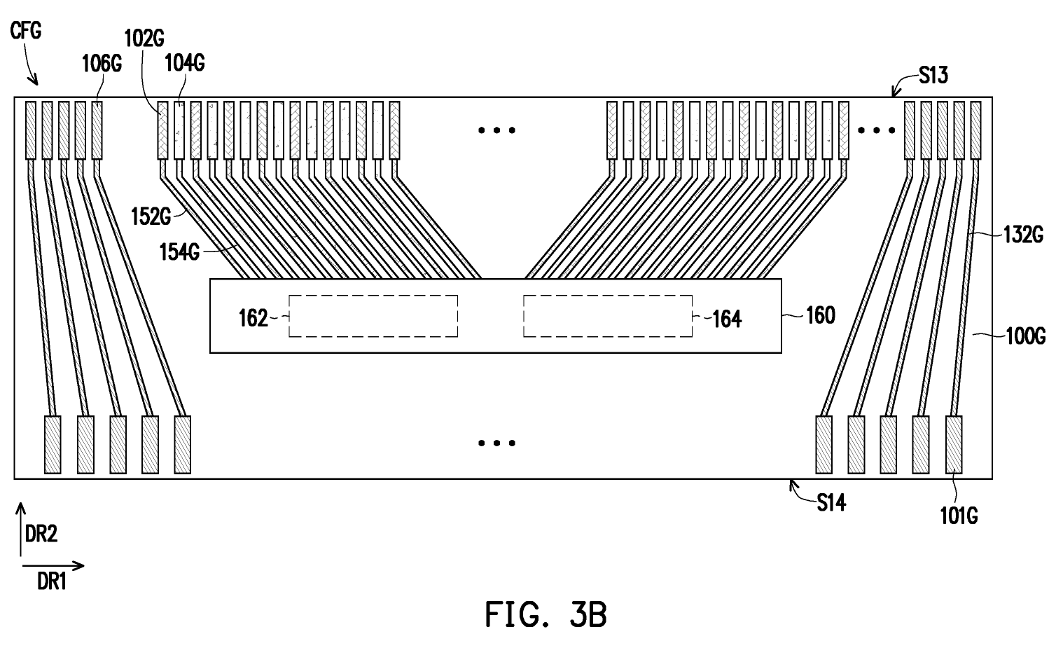

FIG. 3A is a top view schematic diagram of an LED display device 10C according to an embodiment of the invention. FIG. 3B is a top view schematic diagram of the chip on film package structure CFG of FIG. 3A. Referring to FIG. 3A, the LED display device 10C may be a tiled display device, and may include multiple light-emitting diode display panels 500 tiled together. Each light-emitting diode display panel 500 may include multiple pixel structures 510.

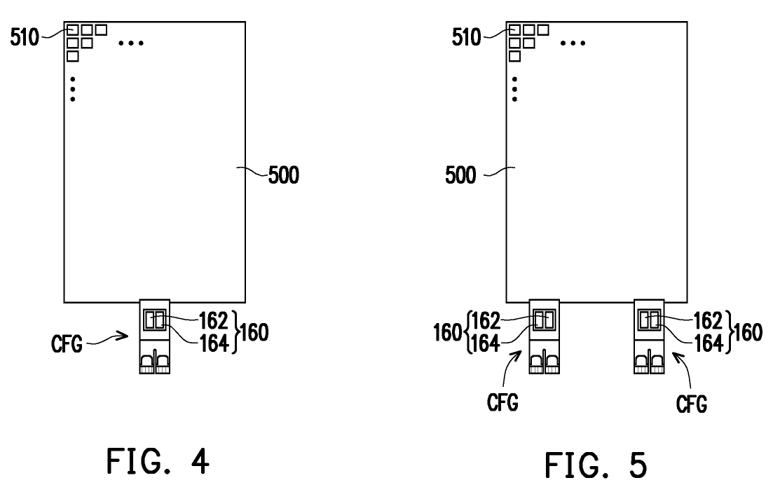

In some embodiments, each light-emitting diode display panel 500 may be electrically connected to multiple chip on film package structures CFG, which may contain the same or different circuits. Although in FIG. 3A each light-emitting diode display panel 500 is electrically connected to three chip on film package structures CFG, the invention is not limited thereto. In other embodiments, one chip on film package structure CFG may be connected to the light-emitting diode display panel 500, as shown in FIG. 4. In other embodiments, two chip on film package structures CFG may be connected to the light-emitting diode display panel 500, as shown in FIG. 5.

The chip on film package structure CFG may include an integrated chip 160 and a circuit board 100G. The integrated chip 160 may include a first circuit 162 and a second circuit 164. The first circuit 162 and the second circuit 164 may be any two combinations of a light-emitting signal control circuit, a gate signal control circuit, a data signal control circuit, and a reset signal control circuit. For example, the first circuit 162 may be a light-emitting signal control circuit, while the second circuit 164 may be a gate signal control circuit, a data signal control circuit, or a reset signal control circuit.

In some embodiments, the first circuit 162 may be a light-emitting signal control circuit, while the second circuit 164 may be a data signal control circuit. In this case, the integrated chip 160 may have the functions of outputting light-emitting signals and outputting data signals. For example, among the three chip on film package structures CFG connected to each light-emitting diode display panel 500 in FIG. 3A, the integrated chip 160 of one of them may have the functions of outputting light-emitting signals and outputting data signals.

In some embodiments, the first circuit 162 may be a reset signal control circuit, while the second circuit 164 may be a data signal control circuit. In this case, the integrated chip 160 may have the functions of outputting reset signals and outputting data signals. For example, among the three chip on film package structures CFG connected to each light-emitting diode display panel 500 in FIG. 3A, the integrated chip 160 on another one of them may have the functions of outputting reset signals and outputting data signals.

In some embodiments, the first circuit 162 may be a gate signal control circuit, while the second circuit 164 may be a data signal control circuit. In this case, the integrated chip 160 may have the functions of outputting gate signals and outputting data signals. For example, among the three chip on film package structures CFG connected to each light-emitting diode display panel 500 in FIG. 3A, the integrated chip 160 on the last one of them may have the functions of outputting gate signals and outputting data signals.

Each LED display panel 500 may be electrically connected to the first circuit board 200 through multiple chip on film package structures CFG.

Referring to FIG. 3A and FIG. 3B, the chip on film package structure CFG may include an integrated chip 160 and a circuit board 100G. The circuit board 100G may be, for example, a flexible circuit board, and may include multiple input pads 101G, multiple first signal output pads 102G, multiple second signal output pads 104G, multiple power transmission pads 106G, multiple power transmission lines 132G, multiple first signal output lines 152G, and multiple second signal output lines 154G. In some embodiments, the circuit board 100G may include a flexible substrate and multiple conductive layers and multiple insulation layers disposed on the flexible substrate, and the aforementioned pads, power transmission lines, and signal output lines may be distributed in the same or different conductive layers.

In some embodiments, the first signal output pads 102G, the second signal output pads 104G, and the power transmission pads 106G may be arranged along the first direction DR1 at a location approaching the first side S13, and may be bonded to the light-emitting diode display panel 500.

The input pads 101G may be arranged along the first direction DR1 at a location approaching the second side S14, and may be bonded to the first circuit board 200.

The power transmission lines 132G may connect the power transmission pads 106G to corresponding input pads 101G. For example, power signals may be transmitted to the light-emitting diode display panel 500 through corresponding input pads 101G, power transmission lines 132G, and power transmission pads 106G, and may be further transmitted to corresponding pixel structures 510.

The integrated chip 160 may be bonded to the circuit board 100G. In some embodiments, the first circuit 162 in the integrated chip 160 may be electrically connected to the first signal output lines 152G, and may output signals (for example, light emission signals) to the first signal output pads 102G through the first signal output lines 152G; the second circuit 164 in the integrated chip 160 may be electrically connected to the second signal output lines 154G, and may output signals (for example, gate signals, data signals, or reset signals) to the second signal output pads 104G through the second signal output lines 154G. In some embodiments, the circuit board 100G may further include multiple signal input lines (not shown). Some of the input pads 101G may provide clock control signals and/or data signals to the integrated chip 160 through the signal input lines.

In this embodiment, various circuits with different functions may be integrated into one integrated chip, and the integrated chip may be disposed within one chip on film package structure. Compared to setting multiple chips with different functions separately within different chip on film package structures, this may reduce the total number of chip on film package structures, thereby reducing the quantity and cost of chip on film package structures. As the number of chip on film package structures may be reduced, the border size of the light-emitting diode display device may be minimized, which in turn may reduce the seam of the tiled display device.

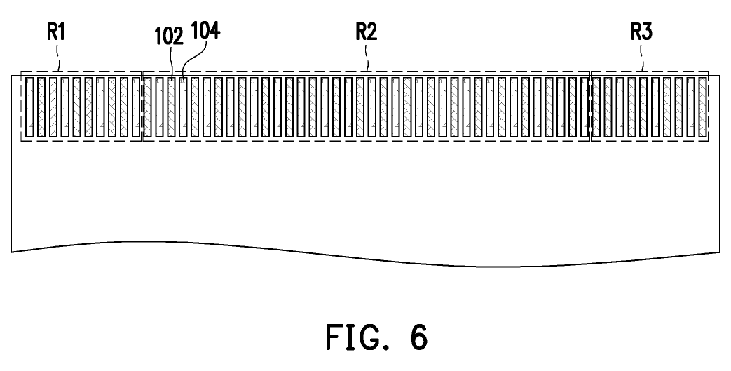

FIG. 6 to FIG. 8 are schematic partial top view of chip on film package structures according to some embodiments of the invention. FIG. 6 to FIG. 8 may be used to illustrate various arrangement methods of the first signal output pads and the second signal output pads in the chip on film package structure. The first signal output pads and the second signal output pads in the chip on film package structures of any of the aforementioned embodiments may be laid out using the methods shown in FIG. 6 to FIG. 8.

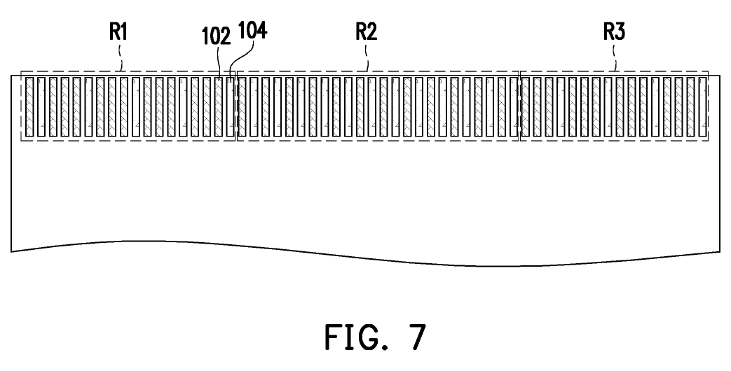

Referring to FIG. 6 and FIG. 7, the first region R1, the second region R2, and the third region R3 may be arranged along the first side of the chip on film package structure. In the first region R1 and the third region R3, the quantity of the first signal output pads 102 may be different from the quantity of the second signal output pads 104. For example, in the first region R1 and the third region R3, groups of two to five first signal output pads 102 (e.g., two to three or three to five) are interlaced with one second signal output pad 104. In the second region R2, each second signal output pad 104 is interlaced with one first signal output pad 102. In the first region R1 and the third region R3 of FIG. 6 and FIG. 7, the quantity of the first signal output pads 102 may be greater than the quantity of the second signal output pads 104 as an example, but the invention may not be limited thereto. In other embodiments, in the first region R1 and the third region R3, the quantity of the first signal output pads 102 may be less than the quantity of the second signal output pads 104. For example, groups of two to five second signal output pads 104 (e.g., two to three or three to five) are interlaced with one first signal output pad 102.

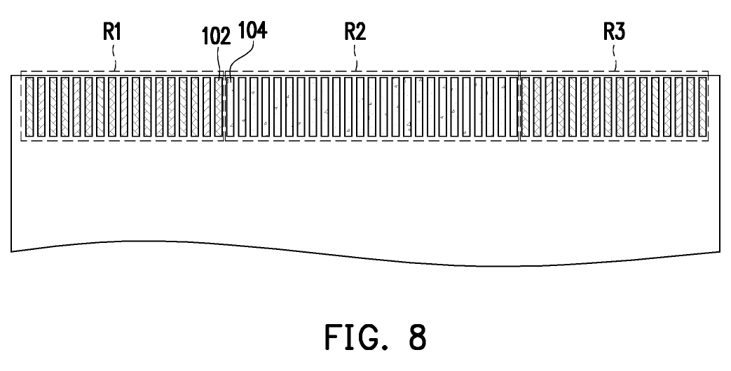

Referring to FIG. 8, in the first region R1 and the third region R3, all of pads may be the first signal output pads 102, while in the second region R2, all of pads may be the second signal output pads 104. In other embodiments, in the second region R2, all of pads may be the first signal output pads 102, while in the first region R1 and the third region R3, all of pads may be the second signal output pads 104.

In any of the above embodiments, the pad layout method of the first region R1 and the third region R3 may be interchanged with the pad layout method of the second region R2.

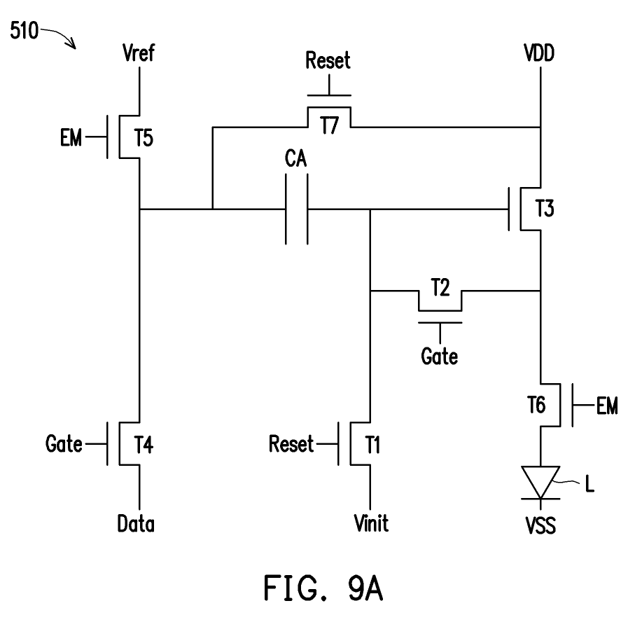

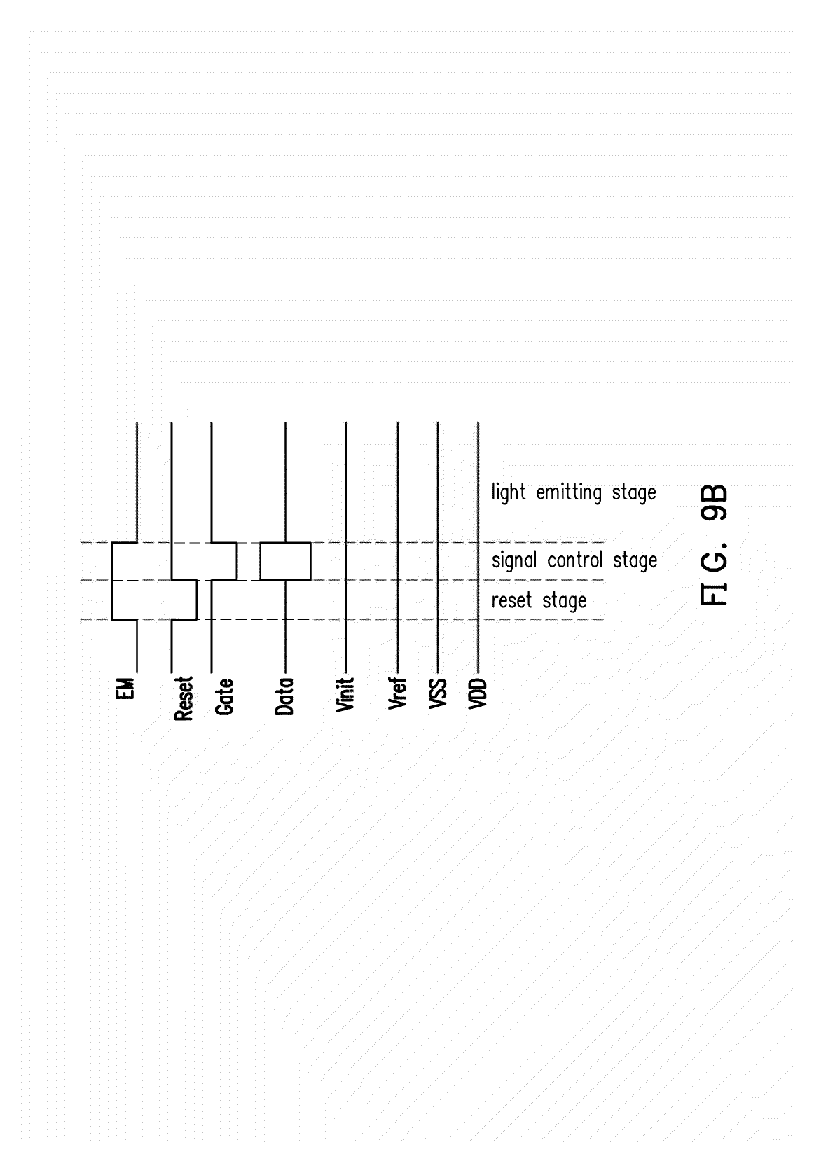

FIG. 9A is a schematic circuit diagram of a pixel structure 510 according to an embodiment of the invention. For example, the pixel structure 510 in any of the aforementioned embodiments may have a circuit diagram as shown in FIG. 9A. Referring to FIG. 9A, the pixel structure 510 may include a first transistor T1, a second transistor T2, a third transistor T3, a fourth transistor T4, a fifth transistor T5, a sixth transistor T6, a seventh transistor T7, a capacitor CA, and an LED L.

The gate of the first transistor T1 may be connected to the reset signal line Reset (for example, used to transmit the reset signal output by the chip on film package structure in the aforementioned embodiments). The first terminal of the first transistor T1 may be connected to the initial signal line Vinit, and the second terminal may be connected to the first terminal of the second transistor T2, the first terminal of the capacitor CA, and the gate of the third transistor T3.

The gate of the second transistor T2 may be connected to the gate signal line Gate (for example, used to transmit the gate signal output by the chip on film package structure in the aforementioned embodiments). The second terminal of the second transistor T2 may be connected to the first terminal of the sixth transistor T6 and the first terminal of the third transistor T3.

The second terminal of the third transistor T3 may be connected to the first terminal of the seventh transistor T7 and the first power signal line VDD.

The gate of the fourth transistor T4 may be connected to the gate signal line Gate. The first terminal of the fourth transistor T4 may be connected to the data signal line Data (for example, used to transmit the data signal output by the chip on film package structure in the aforementioned embodiments). The second terminal of the fourth transistor T4 may be connected to the first terminal of the fifth transistor T5, the second terminal of the seventh transistor T7, and the second terminal of the capacitor CA.

The gate of the fifth transistor T5 may be connected to the light-emitting signal line EM (for example, used to transmit the light emission signal output by the chip on film package structure in the aforementioned embodiments). The second terminal of the fifth transistor T5 may be connected to the reference voltage signal line Vref.

The gate of the sixth transistor T6 may be connected to the light-emitting signal line EM. The second terminal of the sixth transistor T6 may be connected to the first terminal of the LED L.

The gate of the seventh transistor T7 may be connected to the reset signal line Reset.

The second terminal of the LED L may be connected to the second power signal line VSS.

In this embodiment, the pixel structure 510 may include a 7T1C (7 transistors and 1 capacitor) architecture as an example, but the invention may not be limited thereto. The pixel structure 510 may also include other circuit architectures, for example, a 2T1C architecture, a 6T1C architecture, a 7T1C architecture, a 7T2C architecture, an 8T1C architecture, or any possible architecture.

FIG. 9B is a timing diagram of signals for operating the pixel structure according to an embodiment of the invention. In this embodiment, a P-channel Metal-Oxide-Semiconductor (PMOS) transistor architecture may be exemplified, where providing a low electric potential to the gate of the transistor may turn on the transistor, and providing a high electric potential to the gate of the transistor may turn off the transistor, but the invention may not be limited to this. In other embodiments, an N-channel Metal-Oxide-Semiconductor (NMOS) transistor architecture may be selected, and providing a low electric potential to the gate of the transistor may turn off the transistor, while providing a high electric potential to the gate of the transistor may turn on the transistor. Referring to FIG. 9A and FIG. 9B, when the LED display device displays an image, each frame may include a reset stage, a signal control stage, and a light-emitting stage. In the reset stage, the reset signal line Reset may provide a low electric potential to turn on the first transistor T1 and the seventh transistor T7, while the gate signal line Gate and the light-emitting signal line EM may both provide high electric potentials to turn off the second transistor T2, the fourth transistor T4, the fifth transistor T5, and the sixth transistor T6. As a result, the electric potentials at both ends of the capacitor CA may be provided by the first power signal line VDD and the initial signal line Vinit, respectively. This process may be to reset the electric potential stored in the capacitor CA from the previous frame.

In the signal control stage, the reset signal line Reset and the light-emitting signal line EM may both provide high electric potentials to turn off the first transistor T1, the fifth transistor T5, the sixth transistor T6, and the seventh transistor T7, while the gate signal line Gate may provide a low electric potential to turn on the second transistor T2 and the fourth transistor T4, allowing the data signal line Data to input the data line signal to the capacitor CA, causing the capacitor CA to store the light-emitting voltage for the light-emitting stage.

In the light-emitting stage, the light-emitting signal line EM may provide a low electric potential to turn on the fifth transistor T5 and the sixth transistor T6, while the gate signal line Gate and the reset signal line Reset may both provide high electric potentials to turn off the first transistor T1, the second transistor T2, the fourth transistor T4, and the seventh transistor T7. As a result, the reference voltage signal line Vref may provide a reference voltage signal to the capacitor CA.

Based on the above, various signals provided by the chip on film package structure may be utilized to operate the pixel structure. As multiple chips or circuits are integrated into one chip on film package structure, the quantity and cost of chip on film package structures required may be reduced.

What is claimed is:

1. A light-emitting diode (LED) display device, comprising:
an LED display panel; and
a first chip on film package structure, bonded to the LED display panel, and comprising:
a first chip, comprising a plurality of first signal output bumps and a plurality of first dummy bumps;
a second chip, comprising a plurality of second signal output bumps; and
a first circuit board, comprising:
a plurality of first signal output lines, respectively electrically connected to the plurality of first signal output bumps; and
a plurality of second signal output lines, respectively electrically connected to the plurality of second signal output bumps, and at least part of the plurality of second signal output lines respectively electrically connected to the plurality of first dummy bumps, wherein one of the first chip and the second chip is a light-emitting signal control chip.

2. The LED display device of claim 1, wherein another one of the first chip and the second chip is a gate signal control chip, a data signal control chip or a reset signal control chip.

3. The LED display device of claim 1, wherein the second chip comprises a plurality of second dummy bumps, and at least part of the plurality of first signal output lines are respectively electrically connected to the plurality of second dummy bumps.

4. The LED display device of claim 3, further comprising:
a plurality of first connection lines, respectively extending from the plurality of second dummy bumps to part of the plurality of first signal output bumps; and
a plurality of second connection lines, respectively extending from the plurality of first dummy bumps to part of the plurality of second signal output bumps.

5. The LED display device of claim 1, further comprising:
a second chip on film package structure, bonded to the LED display panel, wherein the second chip on film package structure comprises:
a third chip, comprising a plurality of third signal output bumps and a plurality of third dummy bumps;
a fourth chip, comprising a plurality of fourth signal output bumps; and
a second circuit board, comprising:
a plurality of third signal output lines, respectively electrically connected to the plurality of third signal output bumps; and
a plurality of fourth signal output lines, respectively electrically connected to the plurality of fourth signal output bumps, and at least part of the plurality of fourth signal output lines respectively electrically connected to the plurality of third dummy bumps, wherein the third chip is a gate signal control chip, and the fourth chip is a data signal control chip.

6. The LED display device of claim 1, wherein the plurality of first signal output bumps and the plurality of first dummy bumps are arranged in a staggered manner.

7. The LED display device of claim 1, wherein the first chip is the light-emitting signal control chip, and the first chip comprises a light-emitting signal control circuit, wherein the light-emitting signal control circuit is electrically connected to the plurality of first signal output bumps.

8. The LED display device of claim 1, wherein the first circuit board further comprises:
a plurality of first signal output pads, electrically connected to the plurality of first signal output lines;
a plurality of second signal output pads, electrically connected to the plurality of second signal output lines, wherein the plurality of first signal output pads and the plurality of second signal output pads are arranged along a first side of the first chip on film package structure, and bonded to the LED display panel; and
a plurality of input pads, arranged along a second side of the first chip on film package structure opposite to the first side, wherein an arrangement direction of the first chip and the second chip is staggered with a virtual connection line between the first side and the second side.

9. The LED display device of claim 1, wherein the first circuit board further comprises:
a plurality of first signal output pads, electrically connected to the plurality of first signal output lines;
a plurality of second signal output pads, electrically connected to the plurality of second signal output lines, wherein the plurality of first signal output pads and the plurality of second signal output pads are arranged along a first side of the first chip on film package structure, and bonded to the LED display panel; and
a plurality of input pads, arranged along a second side of the first chip on film package structure opposite to the first side, wherein the first chip is located between the second chip and the plurality of second signal output pads.

10. A light-emitting diode (LED) display device, comprising:
an LED display panel; and
a first chip on film package structure, bonded to the LED display panel, and comprising:
a first chip, comprising a plurality of first signal output bumps;
a second chip, comprising a plurality of second signal output bumps, wherein one of the first chip and the second chip is a light-emitting signal control chip; and
a first circuit board, comprising:
a plurality of first signal output lines, respectively electrically connected to the plurality of first signal output bumps; and
a plurality of second signal output lines, respectively electrically connected to the plurality of second signal output bumps, and at least part of the plurality of second signal output lines extend from beneath one side of the first chip to under the first chip, and extend beyond the first chip from beneath another side of the first chip.

11. A light-emitting diode (LED) display device, comprising:
an LED display panel; and
a chip on film package structure, bonded to the LED display panel, and comprising:
an integrated chip, comprising a first circuit and a second circuit, wherein the first circuit is a light-emitting signal control circuit, wherein the second circuit is a gate signal control circuit, a data signal control circuit or a reset signal control circuit; and
a circuit board, comprising:
a plurality of first signal output lines, electrically connected to the first circuit, wherein the first circuit outputs light-emitting signals to the plurality of first signal output lines; and
a plurality of second signal output lines, electrically connected to the second circuit, and the second circuit outputs gate signals, data signals or reset signals to the plurality of second signal output lines.
